(19) United States
(12) Patent Application Publication
(10) Pub. No.: US 2019/0019848 A1
(43) Pub. Date: Jan. 17, 2019

(54) OLED DISPLAY PANEL AND DISPLAY DEVICE

(71) Applicant: WUHAN CHINA STAR OPTOELECTRONICS SEMICONDUCTOR DISPLAY TECHNOLOGY CO., LTD., Wuhan, Hubei (CN)

(72) Inventors: Liang SUN, Wuhan, Hubei (CN); Nian TIAN, Wuhan, Hubei (CN); Yao-Jen CHANG, Wuhan, Hubei (CN)

(73) Assignee: WUHAN CHINA STAR OPTOELECTRONICS SEMICONDUCTOR DISPLAY TECHNOLOGY CO., LTD., Wuhan, Hubei (CN)

(21) Appl. No.: 15/576,413

(22) PCT Filed: Sep. 4, 2017
(86) PCT No.: PCT/CN2017/100350

§ 371 Date: Nov. 22, 2017

(30) Foreign Application Priority Data
Jul. 12, 2017 (CN) 201710567026.8

(51) Int. Cl. H01L 27/32

(52) U.S. Cl. CPC H01L 27/3218; H01L 51/0011

(57) ABSTRACT

An OLED display panel and a display device are provided. The OLED display panel has at least two pixel group units, and each of the pixel group units has two sub-pixel group units. The sub-pixel group units has a first sub-pixel, two second sub-pixels, and two third sub-pixels. A basic pixel unit consists of any three of the first sub-pixel, a second sub-pixel set, and a third sub-pixel set neighboring each other, where the second sub-pixel set consists of two neighboring second sub-pixels, and the third sub-pixel set consists of two neighboring third sub-pixels.

### FIELD OF THE DISCLOSURE

The present disclosure relates to the technical field of displays, and more particularly to an OLED display panel and a display device.

### BACKGROUND OF THE DISCLOSURE

In flat panel display technologies, organic light-emitting diode (OLED) displays have many advantages, such as being light weight, thin, active emitting, fast responding rates, large viewing angles, wide color gamut, high brightness, low power consumption, and so on, and have gradually become a third generation display technology after liquid crystal displays. Compared to liquid crystal displays (LCD), OLED displays have advantages of higher power-saving, thinner, and wider viewing angles, and therefore the OLED displays are unparalleled. At present, people have increasing demands on detail degree of displaying, i.e., resolution. However, production of OLED display screens with high-quality and high-resolution still faces many challenges.

At present, in terms of fabricating devices, vacuum deposition is the most mature technology to form an OLED organic layer. Small organic molecules are heated, in an evaporation source, to a gaseous state from an aggregate state, to deposit on a substrate located right above the evaporation source. A fine metal mask (FMM) is tightly attached to a lower side of the substrate, and the FMM has a pattern consisting of large number of meshes thereon, such that an uncoated area among other sub-pixels and pixels not to be coated is shielded and a thin film is merely coated on a sub-pixel area to be coated, when a colored sub-pixel is deposited. The FMM is also one of the most critical technologies controlling development of high resolution OLEDs. With increase in resolution requirements, production of metal masks is increasingly difficult. At present, in mainstream arrangements using a RGB Stripe mode and a Pentile mode, each sub-pixel corresponds to each opening of the FMM. In order to avoid color aliasing, a distance of the openings between sub-pixels with different colors has a minimum limit, so as to restrict a further improvement of the resolution.

Furthermore, a sub-pixel rendering (SPR) technology also has a certain position. The SPR technology achieves improvement of sensory resolution by a method of sharing a part of the sub-pixels of neighboring pixels, such that a display can achieve a relatively high sensory resolution in a condition of having identical sub-pixel arrangement density, or such that a demand on a sub-pixel arrangement density of the display is decreased on a condition of keeping an identical sensory resolution unchanged. Therefore, the SPR technology provides a solution to solve the above problem.

### SUMMARY OF THE DISCLOSURE

The present disclosure provides an organic light-emitting diode (OLED) display panel, which can break the limiting of a mask fabricating process and a coating process, so as to raise an image property and effect of an OLED display.

To achieve the above object, a technical solution provided by the present disclosure is as follows:

The present disclosure provides an OLED display panel, including:
at least two pixel group units arranged in a first direction or in a second direction, wherein each of the two pixel group units includes two sub-pixel group units distributed in the second direction, and the sub-pixel group units include a first sub-pixel, two second sub-pixels, and two third sub-pixels;
wherein a second sub-pixel set consists of two neighboring second sub-pixels, and a third sub-pixel set consists of two neighboring third sub-pixels;
wherein a first sub-pixel row formed by the first sub-pixels and a second sub-pixel row formed by the second sub-pixel set are in staggered arrangement along the first direction, and the first sub-pixel row formed by the first sub-pixels and a third sub-pixel row formed by the third sub-pixel set are in staggered arrangement along the first direction;
wherein an area of the first sub-pixel corresponds to an area of a first opening in a mask, and a shape of the first sub-pixel corresponds to a shape of the first opening in the mask;
wherein the two neighboring second sub-pixels are fabricated using the same second opening in a mask process corresponding to the mask, and the two neighboring third sub-pixels are formed using a same third opening in the mask process corresponding to the mask;
wherein a basic pixel unit consists of any three of the first sub-pixel, the second sub-pixel set, and the third sub-pixel set neighboring each other; and
wherein each of the sub-pixel group units is separated to three rows in the second direction, and each of the three rows corresponds to one of the first sub-pixel, the second sub-pixel, and the third sub-pixel.

According to a preferred embodiment of the present disclosure, each of the first sub-pixel, the second sub-pixel, and the third sub-pixel is any one of a red sub-pixel, a green sub-pixel, and a blue sub-pixel, wherein sub-pixel colors corresponding to the first sub-pixel, the second sub-pixel, and the third sub-pixel are different.

According to a preferred embodiment of the present disclosure, the two second sub-pixels of the second sub-pixel set are in a mirror distribution along the second direction, and the two third sub-pixels of the third sub-pixel set are in a mirror distribution along the second direction.

According to a preferred embodiment of the present disclosure, a center line in a lengthways of the first sub-pixel is vertical to a line segment formed by connecting a center point of the second sub-pixel set with a center point of the third sub-pixel set, and the center line intersects the line segment at a midpoint of the line segment.

According to a preferred embodiment of the present disclosure, any two of the first sub-pixel, the second sub-pixel set, and the third sub-pixel set are located in a same column, and the remaining one of the first sub-pixel, the second sub-pixel set, and the third sub-pixel set is located in another column.

According to a preferred embodiment of the present disclosure, permutations and combinations of locations formed by the first sub-pixel, the second sub-pixel set, and the third sub-pixel set of two neighboring sub-pixel group units are different.

According to a preferred embodiment of the present disclosure, sub-pixels in an ith row, an (i+1)st row, and an (i+2)nd row of the pixel group unit in the second direction correspond to one of the first sub-pixel, the second sub-pixel, and the third sub-pixel, respectively, wherein the sub-pixels corresponding to the ith row, the (i+1)st row, and the (i+2)nd row are different, wherein i is a natural number.

According to a preferred embodiment of the present disclosure, the first sub-pixel, the second sub-pixel, and the third sub-pixel are polygonal or circular.

The present disclosure provides a display device, including any one of the OLED display panels described above.

The present disclosure further provides an OLED display panel, including:
at least two pixel group units arranged in a first direction or in a second direction, wherein each of the two pixel group units comprises two sub-pixel group units distributed in the second direction, and the sub-pixel group units include a first sub-pixel, two second sub-pixels, and two third sub-pixels;
wherein a second sub-pixel set consists of two neighboring second sub-pixels, and a third sub-pixel set consists of two neighboring third sub-pixels;
wherein a first sub-pixel row formed by the first sub-pixels and a second sub-pixel row formed by the second sub-pixel set are in staggered arrangement along the first direction, and the first sub-pixel row formed by the first sub-pixels and a third sub-pixel row formed by the third sub-pixel set are in staggered arrangement along the first direction;
wherein a basic pixel unit consists of any three of the first sub-pixel, the second sub-pixel set, and the third sub-pixel set neighboring each other; and
wherein each of the sub-pixel group units is separated into three rows in the second direction, and each of the three rows corresponds to one of the first sub-pixel, the second sub-pixel, and the third sub-pixel.

According to a preferred embodiment of the present disclosure, each of the first sub-pixel, the second sub-pixel, and the third sub-pixel is any one of a red sub-pixel, a green sub-pixel, and a blue sub-pixel, wherein sub-pixel colors corresponding to the first sub-pixel, the second sub-pixel, and the third sub-pixel are different.

According to a preferred embodiment of the present disclosure, the two second sub-pixels of the second sub-pixel set are in a mirror distribution along the second direction, and the two third sub-pixels of the third sub-pixel set are in a mirror distribution along the second direction.

According to a preferred embodiment of the present disclosure, a center line in a lengthways of the first sub-pixel is vertical to a line segment formed by connecting a center point of the second sub-pixel set with a center point of the third sub-pixel set, and the center line intersects the line segment at a midpoint of the line segment.

According to a preferred embodiment of the present disclosure, any two of the first sub-pixel, the second sub-pixel set, and the third sub-pixel set are located in a same column, and the remaining one of the first sub-pixel, the second sub-pixel set, and the third sub-pixel set is located in another column.

According to a preferred embodiment of the present disclosure, permutations and combinations of locations formed by the first sub-pixel, the second sub-pixel set, and the third sub-pixel set of two neighboring sub-pixel group units are different.

According to a preferred embodiment of the present disclosure, sub-pixels in an ith row, an (i+1)st row, and an (i+2)nd row of the pixel group unit in the second direction correspond to one of the first sub-pixel, the second sub-pixel, and the third sub-pixel, respectively, wherein the sub-pixels corresponding to the ith row, the (i+1)st row, and the (i+2)nd row are different, wherein i is a natural number.

According to a preferred embodiment of the present disclosure, the first sub-pixel, the second sub-pixel, and the third sub-pixel are polygonal or circular.

The present disclosure further provides a display device, including any one of the OLED display panels described above.

The beneficial effects of the present disclosure are that: in comparison with conventional technologies, in the display panel in the present disclosure, a sub-pixel sharing method is used between the neighboring sub-pixels or sub-pixel sets, such that an OLED display property and effect is raised on a condition of having identical number of sub-pixels, or such that a demanding on a sub-pixel arrangement density of the display is decreased on a condition of keeping an identical sensory resolution unchanged, i.e. reducing difficulty of a process of a mask. Further, a mask fabricating process and a coating process are reduced by two neighboring sub-pixels sharing a same opening.

### DESCRIPTION OF THE DRAWINGS

In order to more clearly describe embodiments of the present disclosure or technical solutions in a conventional technology, drawings required to be used for the embodiments or descriptions of the conventional technology are simply described hereinafter. Apparently, the drawings described below only illustrate some embodiments of the present disclosure. Those skilled in the art can obtain other drawings based on these drawings disclosed herein without creative effort.

FIG. 1 is a structural schematic diagram of a pixel arrangement structure in a display panel according to embodiment 1 of the present disclosure.

FIG. 2 is a structural schematic diagram of a pixel arrangement structure in a display panel according to embodiment 2 of the present disclosure.

FIG. 3 is a structural schematic diagram of a pixel arrangement structure in a display panel according to embodiment 3 of the present disclosure.

### DETAILED DESCRIPTION OF THE PREFERRED EMBODIMENTS

The following description of each of the embodiments with reference to the appended drawings is used for illustrating specific embodiments which may be used for carrying out the present disclosure. The directional terms described by the present disclosure, such as “upper”, “lower”, “front”, “back”, “left”, “right”, “inner”, “outer”, “side”, etc., are only directions by referring to the accompanying drawings. Thus, the used directional terms are used to describe and understand the present disclosure, but the present disclosure is not limited thereto. In figures, elements with similar structures are indicated by the same numbers.

The present disclosure provides an OLED display panel, which focuses on a conventional OLED display panel which has problems that a mask fabricating process and a coating process are restricted and an OLED display effect not being further improved is induced, and so on. The present embodiment can solve the problems.

FIG. 1 is a structural schematic diagram of a pixel arrangement structure in a display panel according to embodiment 1 of the present disclosure. The display panel includes at least two pixel group units 110 arranged in a first direction or in a second direction. In the present embodiment, the first direction is a horizontal direction, and the second direction is a vertical direction.

Each of the two pixel group units 110 includes two sub-pixel group units 111 distributed in a longitudinal direction, and the sub-pixel group units 111 include a first sub-pixel 112, two second sub-pixels 113, and two third sub-pixels 114, wherein each of the first sub-pixel 112, the second sub-pixel 113, and the third sub-pixel 114 is any one of a red sub-pixel, a green sub-pixel, and a blue sub-pixel, wherein sub-pixel colors corresponding to the first sub-pixel 112, the second sub-pixel 113, and the third sub-pixel 114 are different. For example, when the first sub-pixel 112 is red, the second sub-pixel 113 is blue, and the third sub-pixel 114 is green.

The first sub-pixel 112, the second sub-pixel 113, and the third sub-pixel 114 are polygonal or circular. In the present embodiment, preferably, the first sub-pixel 112, the second sub-pixel 113, and the third sub-pixel 114 are square or rectangular, and rounded corners or chamfering corners are disposed in four corners of the square or the rectangle, to reduce process difficulty and cost.

A second sub-pixel set 115 consists of two neighboring second sub-pixels 113, and a third sub-pixel set 116 consists of two neighboring third sub-pixels 114. The two second sub-pixels of the second sub-pixel set 115 are in a mirror distribution along a center line which is a line segment connected with centers of the two neighboring second sub-pixels 113 in the second sub-pixel set 115. The two third sub-pixels of the third sub-pixel set 114 are in a mirror distribution along a center line which is a line segment connected with centers of the two neighboring third sub-pixels 114 in the third sub-pixel set 116.

Any two of the first sub-pixel 112, the second sub-pixel set 115, and the third sub-pixel set 116 are located in a same column, and the remaining one of the first sub-pixel 112, the second sub-pixel set 115, and the third sub-pixel set 116 is located in another column. In the present embodiment, the first sub-pixel 112 is located in a single column, and the second sub-pixel set 115 and the third sub-pixel set 116 are located in another same column.

A center line in a lengthways of the first sub-pixel 112 is vertical to a line segment formed by connecting a center point of the second sub-pixel set 115 with a center point of the third sub-pixel set 116, and the center line intersects the line segment at a midpoint of the line segment.

A first sub-pixel row formed by the first sub-pixels 112 and a second sub-pixel row formed by the second sub-pixel set 115 are in staggered arrangement along the horizontal direction, and the first sub-pixel row formed by the first sub-pixels 112 and a third sub-pixel row formed by the third sub-pixel set 116 are in staggered arrangement along the horizontal direction.

Permutations and combinations of locations formed by the first sub-pixel 112, the second sub-pixel set 115, and the third sub-pixel set 116 of two neighboring sub-pixel group units 111 are different.

Each of the sub-pixel group units 111 is separated into three rows in the second direction, and each of the three rows corresponds to one of the first sub-pixel 112, the second sub-pixel 113, and the third sub-pixel 114. Sub-pixels in an ith row, an (i+1)st row, and an (i+2)nd row of the pixel group unit 111 in the second direction correspond to one of the first sub-pixel 112, the second sub-pixel 113, and the third sub-pixel 114, respectively, wherein the sub-pixels corresponding to the ith row, the (i+1)st row, and the (i+2)nd row are different, wherein i is a natural number.

For example, in a pixel group unit 110, a second sub-pixel set 115, a first sub-pixel 112, a third sub-pixel set 116, a second sub-pixel set 115, a first sub-pixel 112, and a third sub-pixel set 116 are respectively in a vertical direction (from top to bottom).

In the OLED display panel, a basic pixel unit consists of a portion surrounded by line segments which are formed by connecting with centers of any three of the first sub-pixel 112, the second sub-pixel set 115, and the third sub-pixel set 116 neighboring each other, such that each of the first sub-pixel 112, the second sub-pixel set 115, and the third sub-pixel set 116 can be shared by neighboring sub-pixels.

The above pixel structure achieves improvement of sensory resolution by a method of sharing a part of sub-pixels of neighboring pixels, which means that a display can achieve relatively high sensory resolution on a condition of having identical sub-pixel arrangement density, or such that a demand on a sub-pixel arrangement density of the display is decreased on a condition of keeping an identical sensory resolution unchanged.

Further, an area of the first sub-pixel 112 corresponds to an area of a first opening in a mask, and a shape of the first sub-pixel 112 corresponds to a shape of the first opening in the mask, wherein the two neighboring second sub-pixels are fabricated using the same second opening in a mask process corresponding to the mask.

Similarly, the two neighboring third sub-pixels 114 are formed using a same third opening in the mask process corresponding to the mask.

In the mask process corresponding to the mask, an opening is shared between sub-pixels, in a condition of ensuring the resolution unchanged, process difficulty of the mask can be greatly decreased. For example, when a process is performed on the second sub-pixels 113, an opening of the mask corresponds to an area of the two neighboring second sub-pixels 113 and an area located between the two neighboring second sub-pixels 113.

Further, two different driving circuits are disposed on an area of the neighboring second sub-pixels 113, so as to control the area of the neighboring second sub-pixels 113, or a driving circuit is disposed to drive the neighboring second sub-pixels 113 together.

Similarly, two different driving circuits are disposed on an area of the neighboring third sub-pixels 114, so as to control the area of the neighboring third sub-pixels 114, or a driving circuit is disposed to drive the neighboring third sub-pixels 114, together.

This kind of process method uses a combination of an emitting layer and a driving circuit, such that two sub-pixels can be processed by a same mask opening, and process difficulty of the mask is decreased. Further, in a same space, a number of the sub-pixels can be increased, so as to improve image quality of the display screen.

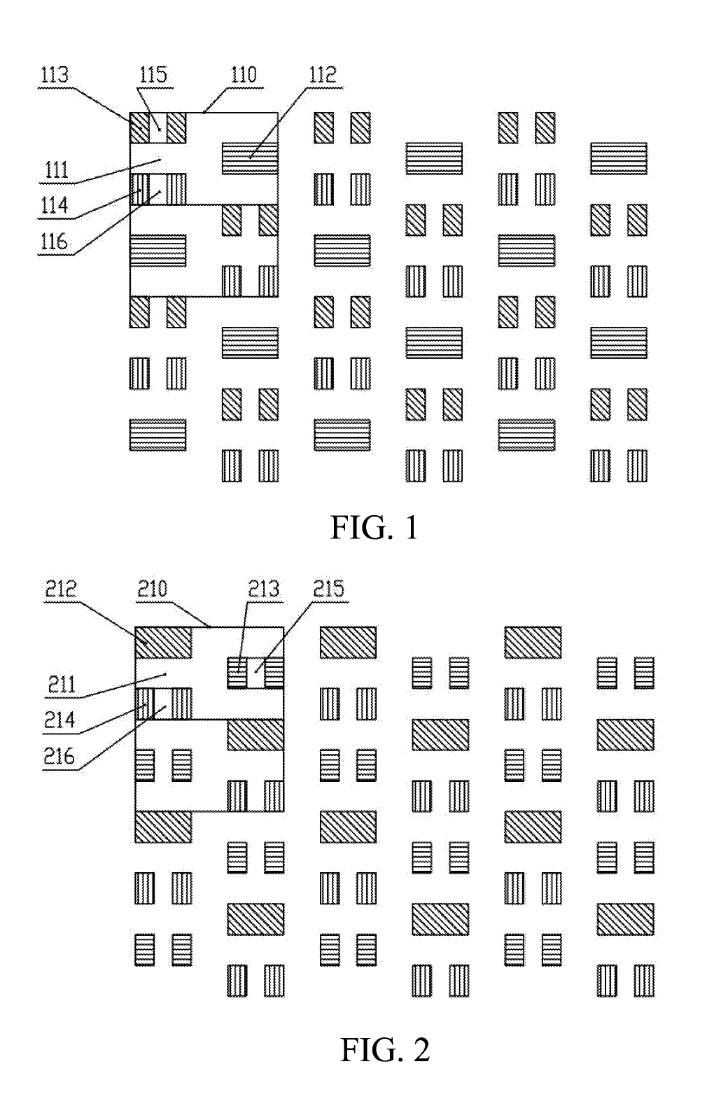

FIG. 2 is a structural schematic diagram of a pixel arrangement structure in a display panel according to embodiment 2 of the present disclosure. In an pixel group unit 210 of the present embodiment, a first sub-pixel 212, a second sub-pixel set 215, a third sub-pixel set 216, a first sub-pixel 212, a second sub-pixel set 215, and a third sub-pixel set 216 are respectively located in a vertical direction (from top to bottom). Other features are identical to those in the embodiment 1 and are not repeated here again.

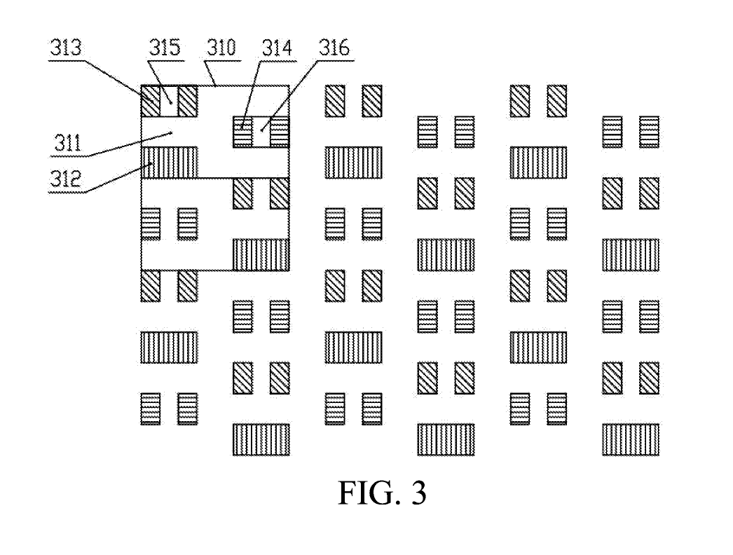

FIG. 3 is a structural schematic diagram of a pixel arrangement structure in a display panel according to embodiment 3 of the present disclosure. In an pixel group unit 310 of the present embodiment, a second sub-pixel set 315, a third sub-pixel set 316, a first sub-pixel 312, a second sub-pixel set 315, a third sub-pixel set 316, and a first sub-pixel 312 are respectively located in a vertical direction (from top to bottom). Other features are identical to those in the embodiment 1 and are not repeated here again.

The present disclosure further provides a display device including one of the OLED pixel arrangement structures provided by the above embodiments 1 to 3, which are not repeated here again. The display device can be an OLED display panel, a mobile phone, a flat-panel television, and so on, which is not limited thereto here.

The present disclosure provides an OLED display panel and a display device. In the display panel, a sub-pixel sharing method is used between the neighboring sub-pixels or sub-pixel sets, such that an OLED display property and effect is raised in a condition of having identical number of sub-pixels, or such that a demand on a sub-pixel arrangement density of the display is decreased on a condition of keeping an identical sensory resolution unchanged, i.e., reducing difficulty of a process of a mask. Further, a mask fabricating process and a coating process are reduced by two neighboring sub-pixels sharing a same opening.

From the above, the present disclosure has been described with a preferred embodiment thereof and it is understood that many changes and modifications to the described embodiment can be carried out without departing from the scope and the spirit of the disclosure that is intended to be limited only by the appended claims.

As described above, although the present disclosure has been described in preferred embodiments, they are not intended to limit the disclosure. One of ordinary skill in the art, without departing from the spirit and scope of the disclosure within, can make various modifications and variations, so the range of the scope of the disclosure is defined by the claims.

1. An organic light emitting diode (OLED) display panel, comprising:
at least two pixel group units arranged in a first direction or in a second direction, wherein each of the two pixel group units comprises two sub-pixel group units distributed in the second direction, and the sub-pixel group units comprise a first sub-pixel, two second sub-pixels, and two third sub-pixels;
wherein a second sub-pixel set consists of two neighboring second sub-pixels, and a third sub-pixel set consists of two neighboring third sub-pixels;
wherein a first sub-pixel row formed by the first sub-pixels and a second sub-pixel row formed by the second sub-pixel set are in staggered arrangement along the first direction, and the first sub-pixel row formed by the first sub-pixels and a third sub-pixel row formed by the third sub-pixel set are in staggered arrangement along the first direction;
wherein an area of the first sub-pixel corresponds to an area of a first opening in a mask, and a shape of the first sub-pixel corresponds to a shape of the first opening in the mask;
wherein the two neighboring second sub-pixels are fabricated using the same second opening in a mask process corresponding to the mask, and the two neighboring third sub-pixels are formed using a same third opening in the mask process corresponding to the mask;
wherein a basic pixel unit consists of any three of the first sub-pixel, the second sub-pixel set, and the third sub-pixel set neighboring each other; and
wherein each of the sub-pixel group units is separated into three rows in the second direction, and each of the three rows corresponds to one of the first sub-pixel, the second sub-pixel, and the third sub-pixel.

2. The OLED display panel according to claim 1, wherein each of the first sub-pixel, the second sub-pixel, and the third sub-pixel is any one of a red sub-pixel, a green sub-pixel, and a blue sub-pixel, wherein sub-pixel colors corresponding to the first sub-pixel, the second sub-pixel, and the third sub-pixel are different.

3. The OLED display panel according to claim 1, wherein the two second sub-pixels of the second sub-pixel set are in a mirror distribution along the second direction, and the two third sub-pixels of the third sub-pixel set are in a mirror distribution along the second direction.

4. The OLED display panel according to claim 1, wherein a center line in a lengthways of the first sub-pixel is vertical to a line segment formed by connecting a center point of the second sub-pixel set with a center point of the third sub-pixel set, and the center line intersects the line segment at a midpoint of the line segment.

5. The OLED display panel according to claim 1, wherein any two of the first sub-pixel, the second sub-pixel set, and the third sub-pixel set are located in a same column, and the remaining one of the first sub-pixel, the second sub-pixel set, and the third sub-pixel set is located in another column.

6. The OLED display panel according to claim 1, wherein permutations and combinations of locations formed by the first sub-pixel, the second sub-pixel set, and the third sub-pixel set of two neighboring sub-pixel group units are different.

7. The OLED display panel according to claim 1, wherein sub-pixels in an ith row, an (i+1)st row, and an (i+2)nd row of the pixel group unit in the second direction correspond to one of the first sub-pixel, the second sub-pixel, and the third sub-pixel, respectively, wherein the sub-pixels corresponding to the ith row, the (i+1)st row, and the (i+2)nd row are different, wherein i is a natural number.

8. The OLED display panel according to claim 1, wherein the first sub-pixel, the second sub-pixel, and the third sub-pixel are polygonal or circular.

9. (canceled)

10. An OLED display panel, comprising:
at least two pixel group units arranged in a first direction or in a second direction, wherein each of the two pixel group units comprises two sub-pixel group units distributed in the second direction, and the sub-pixel group units comprise a first sub-pixel, two second sub-pixels, and two third sub-pixels;
wherein a second sub-pixel set consists of two neighboring second sub-pixels, and a third sub-pixel set consists of two neighboring third sub-pixels;
wherein a first sub-pixel row formed by the first sub-pixels and a second sub-pixel row formed by the second sub-pixel set are in staggered arrangement along the first direction, and the first sub-pixel row formed by the first sub-pixels and a third sub-pixel row formed by the third sub-pixel set are in staggered arrangement along the first direction;
wherein a basic pixel unit consists of any three of the first sub-pixel, the second sub-pixel set, and the third sub-pixel set neighboring each other; and
wherein each of the sub-pixel group units is separated to three rows in the second direction, and each of the three rows corresponds to one of the first sub-pixel, the second sub-pixel, and the third sub-pixel.

11. The OLED display panel according to claim 10, wherein each of the first sub-pixel, the second sub-pixel, and the third sub-pixel is any one of a red sub-pixel, a green sub-pixel, and a blue sub-pixel, wherein sub-pixel colors corresponding to the first sub-pixel, the second sub-pixel, and the third sub-pixel are different.

12. The OLED display panel according to claim 10, wherein the two second sub-pixels of the second sub-pixel set are in a mirror distribution along the second direction, and the two third sub-pixels of the third sub-pixel set are in a mirror distribution along the second direction.

13. The OLED display panel according to claim 10, wherein a center line in a lengthways of the first sub-pixel is vertical to a line segment formed by connecting a center point of the second sub-pixel set with a center point of the third sub-pixel set, and the center line intersects the line segment at a midpoint of the line segment.

14. The OLED display panel according to claim 10, wherein any two of the first sub-pixel, the second sub-pixel set, and the third sub-pixel set are located in a same column, and the remaining one of the first sub-pixel, the second sub-pixel set, and the third sub-pixel set is located in another column.

15. The OLED display panel according to claim 10, wherein permutations and combinations of locations formed by the first sub-pixel, the second sub-pixel set, and the third sub-pixel set of two neighboring sub-pixel group units are different.

16. The OLED display panel according to claim 10, wherein sub-pixels in an ith row, an (i+1)st row, and an (i+2)nd row of the pixel group unit in the second direction correspond to one of the first sub-pixel, the second sub-pixel, and the third sub-pixel, respectively, wherein the sub-pixels corresponding to the ith row, the (i+1)st row, and the (i+2)nd row are different, wherein i is a natural number.

17. The OLED display panel according to claim 10, wherein the first sub-pixel, the second sub-pixel, and the third sub-pixel are polygonal or circular.

18. A display device, comprising an OLED display panel according to claim 10.
